(19) United States
(12) Patent Application Publication
(10) Pub. No.: US 2026/0165206 A1
(43) Pub. Date: Jun. 11, 2026

(54) SEMICONDUCTOR DEVICE AND MANUFACTURING METHOD THEREOF

(71) Applicant: Kioxia Corporation, Tokyo (JP)

(72) Inventors: Kazuma HASEGAWA, Fujisawa Kanagawa (JP); Hideo AOKI, Yokohama Kanagawa (JP); Tsukasa KONNO, Yokohama Kanagawa (JP)

(21) Appl. No.: 19/323,571

(22) Filed: Sep. 9, 2025

(30) Foreign Application Priority Data
Dec. 10, 2024 (JP) 2024-215976

(51) Int. Cl. H01L 25/16; H01L 23/00; H01L 23/49; H01L 25/00

(52) U.S. Cl. CPC H10W 90/00; H10W 72/50; H10W 90/792

(57) ABSTRACT

A semiconductor device includes a first chip, a second chip, and a third chip. The second chip is joined to a first region of an upper face of the first chip, the second chip being electrically connected to the first chip and having a surface area facing the first chip that is smaller than an area of the upper face of the first chip. The third chip is joined to a second region on the upper face of the first chip, the third chip being electrically connected to the first chip and having a surface area facing the first chip that is smaller than the area of the upper face of the first chip. An electrical function of the third chip differs from an electrical function of the second chip.

### CROSS-REFERENCE TO RELATED APPLICATION(S)

This application is based upon and claims the benefit of priority from Japanese Patent Application No. 2024-215976, filed Dec. 10, 2024, the entire contents of which are incorporated herein by reference.

### FIELD

Embodiments described herein relate generally to a semiconductor device and a manufacturing method thereof.

### BACKGROUND

When a semiconductor device is manufactured by bonding together two wafers having semiconductor elements of different sizes (i.e., areas), an unused region is formed after bonding.

### BRIEF DESCRIPTION OF THE DRAWINGS

FIG. 1 is a sectional view showing one example of a configuration of a semiconductor device according to a first embodiment.

FIG. 2 is a sectional view showing one example of a configuration of a semiconductor chip in the semiconductor device according to the first embodiment.

FIG. 3A is a sectional view showing one example of a configuration of a periphery of a metal pad in the semiconductor device according to the first embodiment.

FIG. 3B is a sectional view showing a supply path of electrical power to a functional chip in the semiconductor device according to the first embodiment.

FIG. 4 is a sectional view showing one example of configurations of a memory cell array and a transistor in the semiconductor device according to the first embodiment.

FIG. 5 is a sectional view showing one example of a configuration of a columnar portion in the semiconductor device according to the first embodiment.

FIG. 6A is a sectional view showing one example of a method of manufacturing the semiconductor device according to the first embodiment.

FIG. 6B is a sectional view, continuing from FIG. 6A, showing one example of a method of manufacturing the semiconductor device.

FIG. 6C is a sectional view, continuing from FIG. 6B, showing one example of a method of manufacturing the semiconductor device.

FIG. 6D is a sectional view, continuing from FIG. 6C, showing one example of a method of manufacturing the semiconductor device.

FIG. 6E is a sectional view, continuing from FIG. 6D, showing one example of a method of manufacturing the semiconductor device.

FIG. 6F is a sectional view, continuing from FIG. 6E, showing one example of a method of manufacturing the semiconductor device.

FIG. 6G is a sectional view, continuing from FIG. 6F, showing one example of a method of manufacturing the semiconductor device.

FIG. 6H is a sectional view, continuing from FIG. 6G, showing one example of a method of manufacturing the semiconductor device.

FIG. 6I is a sectional view, continuing from FIG. 6H, showing one example of a method of manufacturing the semiconductor device.

FIG. 6J is a sectional view, continuing from FIG. 6I, showing one example of a method of manufacturing the semiconductor device.

FIG. 6K is a sectional view, continuing from FIG. 6J, showing one example of a method of manufacturing the semiconductor device.

FIG. 6L is a sectional view, continuing from FIG. 6K, showing one example of a method of manufacturing the semiconductor device.

FIG. 6M is a sectional view, continuing from FIG. 6L, showing one example of a method of manufacturing the semiconductor device.

FIG. 7 is a drawing showing one example of sizes of an array chip and the functional chip in the semiconductor device according to the first embodiment.

FIG. 8 is a drawing showing sizes of the array chip and the functional chip in the semiconductor device according to a first modification of the first embodiment.

FIG. 9 is a drawing showing sizes of the array chip and the functional chip in the semiconductor device according to a second modification of the first embodiment.

FIG. 10 is a drawing showing sizes of the array chip and the functional chip in the semiconductor device according to a third modification of the first embodiment.

FIG. 11 is a drawing showing sizes of the array chip and the functional chip in the semiconductor device according to a fourth modification of the first embodiment.

FIG. 12 is a drawing showing sizes of the array chip and the functional chip in the semiconductor device according to a fifth modification of the first embodiment.

FIG. 13 is a sectional view showing the semiconductor device according to a sixth modification of the first embodiment.

FIG. 14 is a sectional view showing the semiconductor device according to a seventh modification of the first embodiment.

FIG. 15 is a sectional view showing the semiconductor device according to an eighth modification of the first embodiment.

FIG. 16 is a side view showing the semiconductor device according to a ninth modification of the first embodiment.

FIG. 17 is a side view showing the semiconductor device according to a tenth modification of the first embodiment.

FIG. 18 is a side view showing one example of a configuration of the semiconductor device according to a second embodiment.

FIG. 19A is a side view showing the semiconductor device according to a first modification of the second embodiment.

FIG. 19B is a side view showing another example of the semiconductor device according to the first modification of the second embodiment.

FIG. 20 is a side view showing the semiconductor device according to a second modification of the second embodiment.

FIG. 21 is a sectional view showing one example of a configuration of a semiconductor chip in the semiconductor device according to a comparative example.

### DETAILED DESCRIPTION

Embodiments provide a semiconductor device, and a manufacturing method thereof, in which a region formed on a semiconductor element as a result of bonding can be utilized effectively.

In general, according to one embodiment, a semiconductor device includes a first chip, a second chip, and a third chip. The second chip is joined to a first region of an upper face of the first chip, the second chip being electrically connected to the first chip and having a surface area facing the first chip that is smaller than an area of the upper face of the first chip. The third chip is joined to a second region of the upper face of the first chip, the third chip being electrically connected to the first chip and having a surface area facing the first chip that is smaller than the area of the upper face of the first chip. An electrical function of the third chip differs from an electrical function of the second chip.

Hereafter, embodiments relating to the present application will be described, with reference to the drawings. The embodiments do not limit the present application. The drawings are schematic or conceptual, and ratios and the like of each portion are not necessarily the same as actual ratios and the like. In the specification and the drawings, identical reference signs are given to elements that are the same as elements previously described in relation to the drawings, and a detailed description is omitted as appropriate.

### First Embodiment

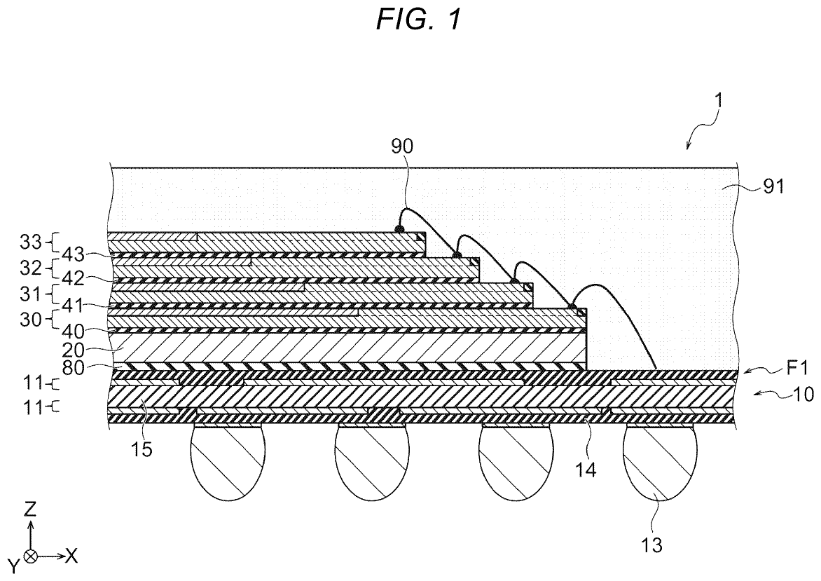

FIG. 1 is a sectional view showing one example of a configuration of a semiconductor device 1 according to a first embodiment. FIG. 1 shows an X direction and a Y direction, which are parallel to a face of a wiring substrate 10 and perpendicular to each other, and a Z direction, which is perpendicular to the face of the wiring substrate 10. In the present specification, a +Z direction is treated as an upward direction, and a −Z direction is treated as a downward direction. The −Z direction may or may not correspond to a direction of gravitational force.

The semiconductor device 1 includes the wiring substrate 10, semiconductor chips 20 and 30 to 33, adhesive layers 40 to 43, a resin layer 80, a bonding wire 90, and a sealing resin 91. The wiring substrate 10 is one example of a substrate, a second substrate, or a third substrate. The semiconductor chip 30 is one example of a first semiconductor chip or a third semiconductor chip. The semiconductor chip 31 is one example of a second semiconductor chip or a fourth semiconductor chip. The bonding wire 90 is one example of a wire, a second wire, or a third wire. The semiconductor device 1 is, for example, a NAND flash memory package.

The wiring substrate 10 is, for example, a printed circuit board or an interposer including a wiring layer 11 and an insulating layer 15. A low resistance metal such as copper (Cu) or nickel (Ni), or an alloy thereof, is used in the wiring layer 11. An insulating material such as a glass epoxy resin is used in the insulating layer 15. In the example shown in FIG. 1, the wiring layer 11 is provided only on an upper face and a lower face of the insulating layer 15. However, the wiring substrate 10 may have a multilayer wiring structure configured with stacking a multiple of the wiring layers 11 and a multiple of the insulating layers 15. The wiring substrate 10 may have a through via (a columnar electrode) that penetrates the upper face and the lower face thereof, as is the case with, for example, an interposer.

A solder resist layer 14 that forms an upper face (a face F1) of the wiring substrate 10 is provided on the wiring layer 11 on the upper face side of the insulating layer 15. The solder resist layer 14 is an insulating layer for protecting the wiring layer 11 from a metal material (not shown) connecting the semiconductor chip 20 and the wiring layer 11, thereby reducing a short-circuit problem.

A solder resist layer 14 that forms a lower face of the wiring substrate 10 is provided on the wiring layer 11 on the lower face side of the insulating layer 15. A metal bump 13 is provided on the wiring layer 11 exposed in the solder resist layer 14. The metal bump 13 is provided in order to electrically connect another part (not shown) and the wiring substrate 10.

The semiconductor chip 20 is, for example, a controller chip that controls a memory chip. A semiconductor element (not shown) is provided on a face of the semiconductor chip 20 facing the wiring substrate 10. The semiconductor element may be, for example, a complementary metal-oxide-semiconductor (CMOS) circuit that configures a controller. An electrode pillar (not shown) electrically connected to the semiconductor element is provided on a lower face of the semiconductor chip 20. A low resistance metal material such as copper or nickel, or an alloy thereof, is used in the electrode pillar.

A metal material is provided on a periphery of the electrode pillar, which acts as a connection bump. The electrode pillar is electrically connected via the metal material to the wiring layer 11 exposed in an aperture portion of the solder resist layer 14. A low resistance metal material such as a solder, silver, or copper is used as the metal material. Because of this, the metal material electrically connects the electrode pillar of the semiconductor chip 20 and the wiring layer 11 of the wiring substrate 10.

The resin layer 80 is provided in a region in a periphery of the metal material and in a region between the semiconductor chip 20 and the wiring substrate 10. The resin layer 80 is, for example, a cured underfill resin, and protects a periphery of the semiconductor chip 20 by covering the periphery.

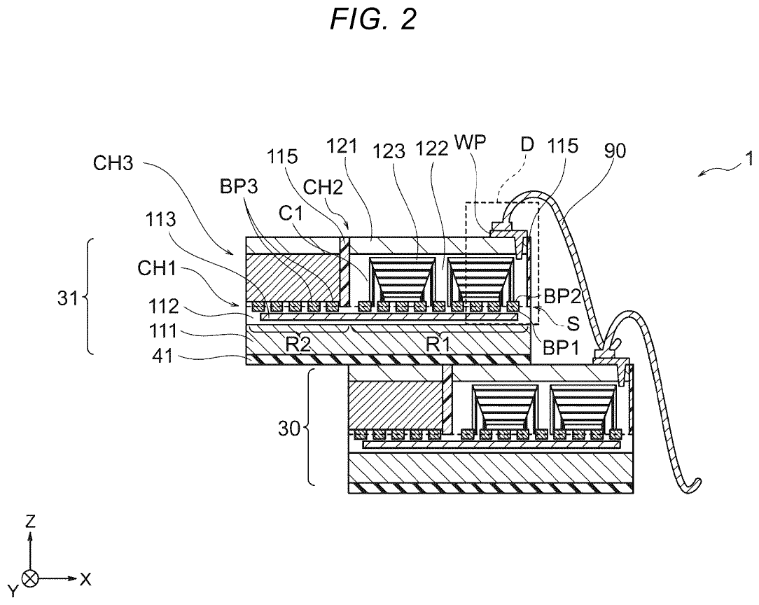

The semiconductor chip 30 is, for example, a memory chip including a NAND flash memory. The semiconductor chip 30 has a semiconductor element (not shown) on an upper face thereof. The semiconductor element may include a memory cell array and a peripheral circuit (a CMOS circuit) thereof. The memory cell array may be a three-dimensional memory cell array such that a multiple of memory cells are disposed three-dimensionally. The semiconductor chip 30 is bonded onto (that is, disposed on) the semiconductor chip 20 via the adhesive layer 40. Also, the semiconductor chip 31 is bonded onto the semiconductor chip 30 via the adhesive layer 41. The semiconductor chip 32 is bonded onto the semiconductor chip 31 via the adhesive layer 42. The semiconductor chip 33 is bonded onto the semiconductor chip 32 via the adhesive layer 43. The semiconductor chips 31 to 33 are, for example, memory chips including a NAND flash memory, in the same way as the semiconductor chip 30. The semiconductor chips 30 to 33 may be the same kind of memory chip. In the drawing, the semiconductor chips 30 to 33, which act as four memory chips, are stacked in addition to the semiconductor chip 20 acting as a controller chip. However, the number of stacked semiconductor chips may also be three or less, or five or more. As will be described hereafter, the semiconductor chips 30 to 33 further have a functional chip CH3 (refer to FIG. 2) as a semiconductor element. The functional chip CH3 is a chip differing from an array chip CH2. Also, the functional chip CH3 is a semiconductor chip other than a memory such as a NAND or a dynamic random-access memory (DRAM). Also, the functional chip CH3 is a chip such that more functions (for example, high-speed operation, high breakdown voltage, power supply stabilization) can be added to a semiconductor storage device than in a case of a semiconductor storage device having only a CMOS circuit and the array chip CH2. The functional chip CH3 can also be called a chip part, an added chip part, or an added chip.

The bonding wire 90 is connected to the wiring substrate 10 and a pad of the semiconductor chips 30 to 33. That is, the bonding wire 90 connects the wiring substrate 10 and a pad of the semiconductor chips 30 to 33. In order to connect using the bonding wire 90, the semiconductor chips 30 to 33 are stacked to be offset by an amount equivalent to the pad. As the semiconductor chip 20 is a flip-chip connected by an electrode pillar, there is no wire bonding. However, the semiconductor chip 20 may also be wire-bonded in addition to being connected by an electrode pillar.

Furthermore, the sealing resin 91 seals the semiconductor chips 20 and 30 to 33, the adhesive layers 40 to 43, the bonding wire 90, and the like. Because of this, the semiconductor device 1 is configured as one semiconductor package in which the multiple of semiconductor chips 20 and 30 to 33 are placed on the wiring substrate 10.

Next, details of the semiconductor chips 30 to 33 will be described.

FIG. 2 is a sectional view showing one example of a configuration of the semiconductor chips 30 and 31 in the semiconductor device 1 according to the first embodiment. FIG. 2 shows the two semiconductor chips 30 and 31. Hereafter, the semiconductor chip 31 will be described, but the semiconductor chips 30, 32, and 33 also have the same configuration as the semiconductor chip 31. In the example shown in FIG. 2, a depiction of the semiconductor chip 20 of FIG. 1 is omitted in order to describe the semiconductor chips 30 and 31 in detail.

The semiconductor chip 31 includes a circuit chip CH1, the array chip CH2, and the functional chip CH3. The circuit chip CH1 is one example of a first chip. The array chip CH2 is one example of a second chip. A DRAM chip, a static random-access memory (SRAM) chip, or the like may be provided as a second chip instead of the array chip CH2. The functional chip CH3 is one example of a third chip.

The circuit chip CH1 functions as a control circuit (that is, a logic circuit) that controls an operation of the array chip CH2. The circuit chip CH1 may further function as a control circuit that controls an operation of the functional chip CH3.

The circuit chip CH1 has a semiconductor substrate 111, an interlayer insulating film 112, a transistor (that is, a semiconductor element) 113, and a metal pad BP1. The metal pad BP1 is one example of a lower pad.

The semiconductor substrate 111 is provided on a lower face side of the circuit chip CH1. The semiconductor substrate 111 is, for example, a silicon (Si) substrate.

The interlayer insulating film 112 is provided on the semiconductor substrate 111. The interlayer insulating film 112 is, for example, a silicon oxide film, or stacked films including a silicon oxide film and another insulating film.

A multiple of the transistors 113 are provided above the semiconductor substrate 111. The transistors 113 are parts of a peripheral circuit (a CMOS circuit), which functions as a control circuit of a memory cell array 123 of the array chip CH2. The control circuit is electrically connected to the metal pad BP1. The transistors 113 may also be parts of a peripheral circuit, which functions as a control circuit of the functional chip CH3.

The metal pad BP1 is provided at an interface (that is, a bonding face) S with the array chip CH2 and the functional chip CH3. The interface S is at an upper face of the circuit chip CH1, a lower face of the array chip CH2, and a lower face of the functional chip CH3. Among a multiple of the metal pads BP1, the metal pads BP1 positioned below the array chip CH2 is joined to corresponding metal pads BP2 of the array chip CH2. Among the multiple of the metal pads BP1, the metal pads BP1 positioned below the functional chip CH3 is joined to corresponding metal pads BP3 of the functional chip CH3. The metal pad BP2 is one example of an upper pad. The metal pads BP1, BP2, and BP3 are, for example, copper layers.

The array chip CH2 is joined (that is, bonded) to the circuit chip CH1 in a first region R1 on the upper face of the circuit chip CH1 in order to be electrically connected to the circuit chip CH1. An area of the array chip CH2 is smaller than an area of the circuit chip CH1. Here, “area” refers to the view in the Z direction.

The array chip CH2 has a semiconductor substrate 121, an interlayer insulating film 122, a memory cell array (that is, a semiconductor element) 123, a contact plug C1, the metal pads BP2, and a metal pad WP. The metal pad WP is one example of a pad, a second pad, a third pad, or a fourth pad.

The semiconductor substrate 121 is provided on an upper face side of the array chip CH2. The semiconductor substrate 121 is, for example, a silicon (Si) substrate.

The interlayer insulating film 122 is provided below the semiconductor substrate 121. The interlayer insulating film 122 is, for example, a silicon oxide film, or stacked films including a silicon oxide film and another insulating film.

The memory cell array 123 is provided below the semiconductor substrate 121. The memory cell array 123 is, for example, a non-volatile memory. The memory cell array 123 has a stepped structure portion. The memory cell array 123 is electrically connected to the metal pads BP2.

The contact plug C1 electrically connects a conductive layer (a word line WL) of the memory cell array 123 and one metal pad BP2.

The metal pads BP2 are provided at the interface S with the circuit chip CH1. The metal pads BP2 are joined to the corresponding metal pads BP1 of the circuit chip CH1. The metal pads BP2 are, for example, copper layers.

The metal pad WP is provided on the upper face of the array chip CH2. The metal pad WP functions as an external connection pad (a bonding pad) of the semiconductor chips 30 to 33. That is, the metal pad WP is connected to the bonding wire 90. Consequently, the bonding wire 90 electrically connects the metal pad WP and the wiring substrate 10. The metal pad WP includes, for example, a conductive metal such as nickel (Ni).

The functional chip CH3 is joined (that is, bonded) to the circuit chip CH1 in a second region R2 differing from the first region R1 on the upper face of the circuit chip CH1 in order to be electrically connected to the circuit chip CH1. As heretofore described, the functional chip CH3 has the metal pads BP3, in the same way as the array chip CH2 has the metal pads BP2. Further, the functional chip CH3 is joined (that is, electrically connected) to the metal pads BP1 of the circuit chip CH1 via the metal pads BP3. An area of the functional chip CH3 is smaller than the area of the circuit chip CH1. Here, “area” refers to the view in the Z direction.

Because the functional chip CH3 is provided in the second region R2, which differs from the first region R1 in which the array chip CH2 is provided, a stepped portion caused by a difference in areas (that is, a size difference) between the circuit chip CH1 and the array chip CH2 can be filled. More specifically, in the example shown in FIG. 2, the upper face of the functional chip CH3 is approximately parallel to the upper face of the array chip CH2. In other words, a thickness (that is, a dimension in the Z direction) of the functional chip CH3 is equal to a thickness of the array chip CH2. As the thickness of the functional chip CH3 is equal to the thickness of the array chip CH2, a stepped portion caused by the difference in areas between the circuit chip CH1 and the array chip CH2 can be filled in such a way as to be approximately flat. The functional chip CH3 of the semiconductor chip 30 supports the semiconductor chip 31 that is on a layer above the semiconductor chip 30. Because the functional chip CH3 on a layer below supports the semiconductor chip 31 on the layer above, assembly risks, such as chip inclination, can be reduced. That is, the areas of the upper faces of the semiconductor chips 30 to 32 on a lower layer side can be increased, so that stacking (die bonding) of the semiconductor chips 30 to 33 can be carried out appropriately.

In the example shown in FIG. 2, a member 115 is provided between the array chip CH2 and the functional chip CH3. The member 115 includes, for example, a resin such as an epoxy resin. When the member 115 is formed of a resin, the member 115 may include a filler. The resin of the member 115 may be a material differing from the sealing resin 91. In this case, for example, the filler size may differ between the member 115 and the sealing resin 91. Meanwhile, the resin of the member 115 may be the same material as the sealing resin 91. In this case, the filler size is the same in the member 115 and the sealing resin 91. The member 115, not being limited to a resin, may be, for example, an insulating film of SiO₂ or the like.

The functional chip CH3 not only functions as a spacer that fills a stepped portion caused by the difference in areas between the circuit chip CH1 and the array chip CH2, but also functions electrically in the semiconductor device. In other words, rather than being a spacer that does not have an electrical function, such as a resin, the functional chip CH3 is a spacer having an electrical function. In the present specification, an “electrical function” of a chip is a function of carrying out a transmission, a reception, or both a transmission and a reception, of at least one of electrical power (that is, at least one of a current or a voltage), a control signal, or data between the chip and another chip.

The area of the functional chip CH3 differs from the area of the array chip CH2. As the area of the functional chip CH3 differs from the area of the array chip CH2, there is no unnecessary limitation on the area of the functional chip CH3. Also, the functional chip CH3 of a preferred area in accordance with the difference in areas between the circuit chip CH1 and the array chip CH2, and with an application of the functional chip CH3, can be selected.

The functional chip CH3 may be a step-up circuit. When the functional chip CH3 is a step-up circuit, the functional chip CH3 can supply a large current to the semiconductor device 1, can supply a multiple of voltages, and can cause power conversion efficiency to improve.

The functional chip CH3 may be a passive component such as a capacitor. When the functional chip CH3 is a passive component, the functional chip CH3 can stabilize a power supply of the semiconductor device 1.

The functional chip CH3 may be a heater. When the functional chip CH3 is a heater, the functional chip CH3 can regenerate the array chip CH2 by heating.

The functional chip CH3 may be a Peltier element. When the functional chip CH3 is a Peltier element, the functional chip CH3 can regenerate and cool the array chip CH2.

The functional chip CH3 may be a RAM such as SRAM or a DRAM. When the functional chip CH3 is a RAM, the functional chip CH3 can cause the semiconductor device 1 to carry out a high-speed operation.

The functional chip CH3 may be a controller that controls the array chip CH2. By disposing the controller adjacent to the array chip CH2, a transmission path between the controller and the array chip CH2 can be shortened. Also, the semiconductor device 1 can be reduced in size.

The functional chip CH3 may be a chip formed of a different kind of material other than silicon (for example, GaN or SiC). Because of this, a breakdown voltage of the functional chip CH3 can be increased, whereby the functional chip CH3 can be utilized in a high voltage power supply.

The functional chip CH3, not being limited to having a single electrical function, may be configured with combining elements having a multiple of electrical functions.

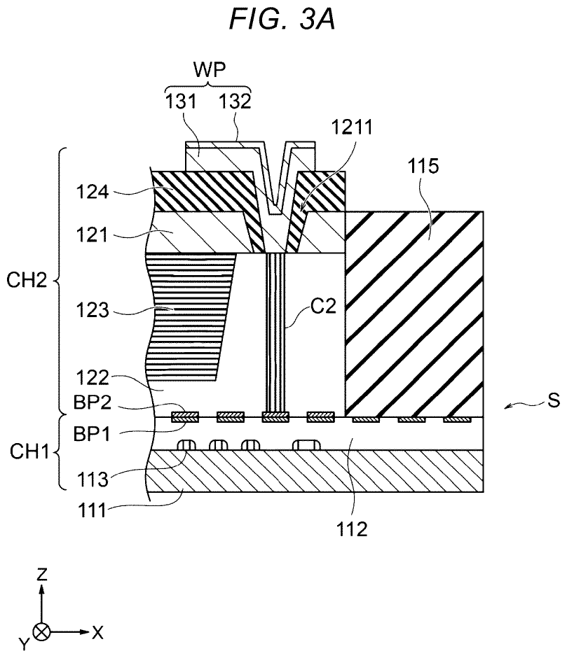

FIG. 3A is a sectional view showing one example of a configuration of a periphery of the metal pad WP in the semiconductor device 1 according to the first embodiment. FIG. 3A is a drawing in which a broken line frame D shown in FIG. 2 is enlarged.

The member 115 may be provided on a right side of the array chip CH2, as shown in FIG. 3A.

A recessed portion 1211 is provided in the semiconductor substrate 121. The recessed portion 1211 is provided to penetrate from an upper face to a lower face of the semiconductor substrate 121.

The array chip CH2 further has an insulating film 124.

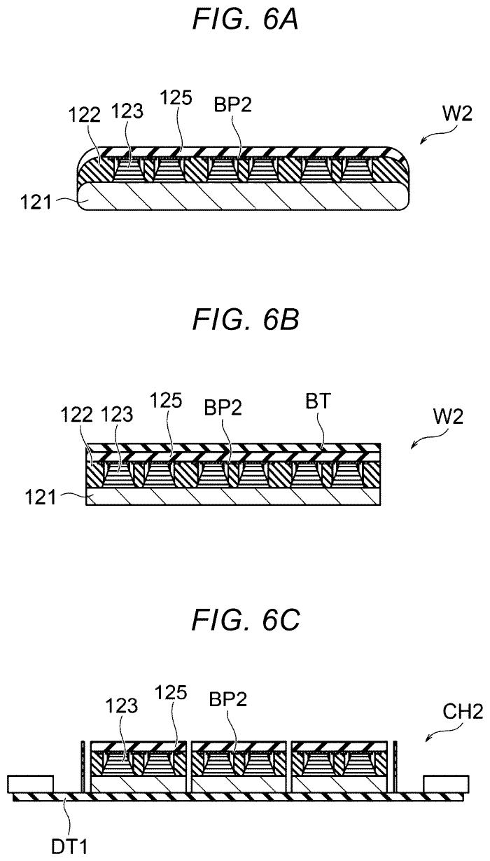

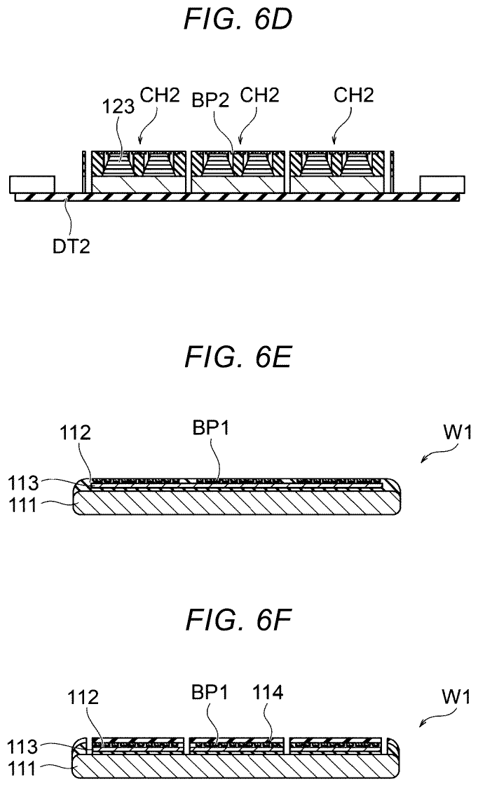

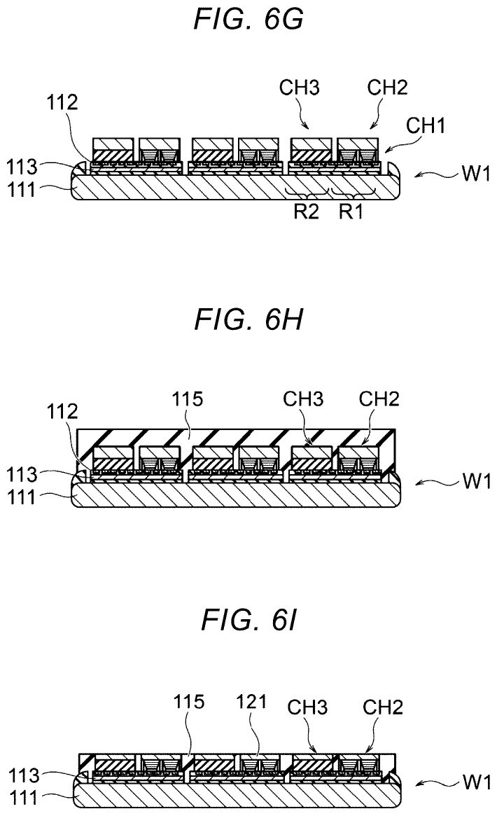

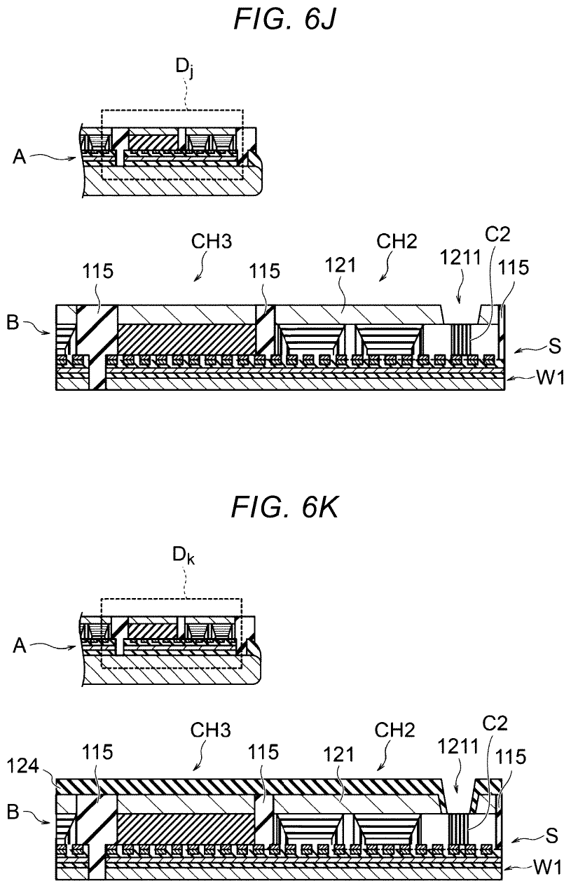

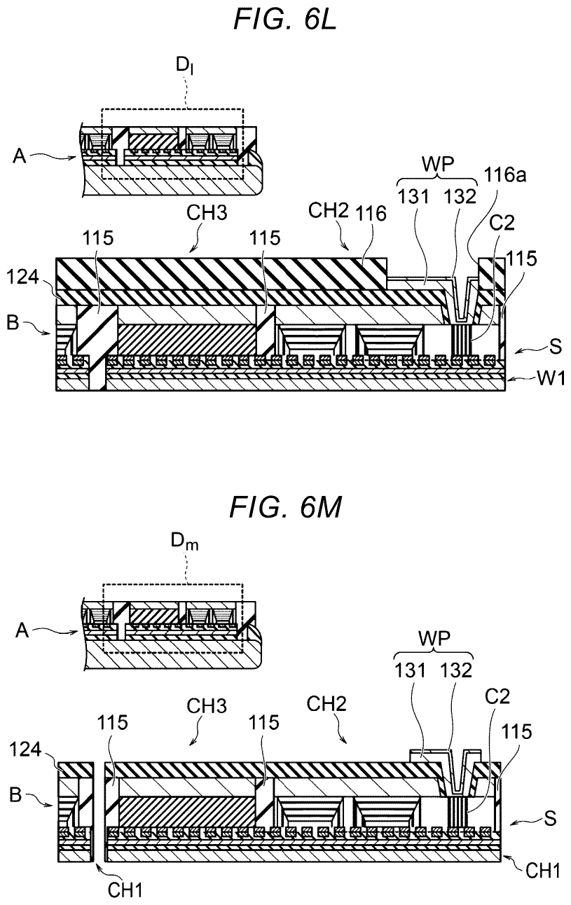

The insulating film 124 is a protective film (a passivation film), and includes, for example, a polyimide. The insulating film 124 is provided on a side face of the recessed portion 1211 and an upper face of the semiconductor substrate 121. In the example shown in FIG. 3A, the insulating film 124 is not provided on the member 115. This is because one portion of the insulating film 124 is removed in order that the insulating film 124 does not remain in a dicing region when dividing into the semiconductor chips 30 to 33. However, the insulating film 124 may be provided on the member 115, and may be provided to cover one portion of the member 115, as shown in FIG. 6M.

The metal pad WP is provided on the semiconductor substrate 121. More specifically, the metal pad WP is provided on the insulating film 124. The metal pad WP is provided to protrude in a lateral direction from the recessed portion 1211 from a bottom face of the recessed portion 1211. That is, the metal pad WP is configured integrated with a wire extending from the bottom face of the recessed portion 1211 to above the semiconductor substrate 121. Consequently, the metal pad WP extends in such a way as to penetrate the semiconductor substrate 121.

The metal pad WP further has metal members 131 and 132.

The metal member 131 includes, for example, nickel (Ni).

The metal member 132 is provided to cover the metal member 131. The metal member 132 includes, for example, gold (Au).

The array chip CH2 further has a contact plug C2.

The contact plug (a columnar electrode) C2 is provided to penetrate the interlayer insulating film 122, and extend from the bottom face of the recessed portion 1211 (a lower face of the metal pad WP) to the metal pad BP2. Consequently, the contact plug C2 electrically connects the metal pad WP and the circuit chip CH1. The contact plug C2 includes, for example, a conductive metal such as tungsten (W).

FIG. 3B is a sectional view showing a supply path P of electrical power to the functional chip CH3 in the semiconductor device 1 according to the first embodiment. Electrical power is supplied from a power supply (not shown) to the array chip CH2 in which the metal pad WP is provided via the bonding wire 90 (refer to FIG. 2), of which one end is connected to the metal pad WP, and the wiring substrate 10, which is connected to the other end of the bonding wire 90. Also, as shown in FIG. 3B, the supply path P of electrical power from the power supply to the functional chip CH3 is formed between the metal pad WP and the functional chip CH3. The supply path P passes through the contact plug C2 provided in the circuit chip C1. This means that even when the metal pad WP is not provided on the functional chip CH3, electrical power can be supplied to the functional chip CH3 via the circuit chip CH1.

Next, configurations of the memory cell array 123 and the transistor 113 will be described.

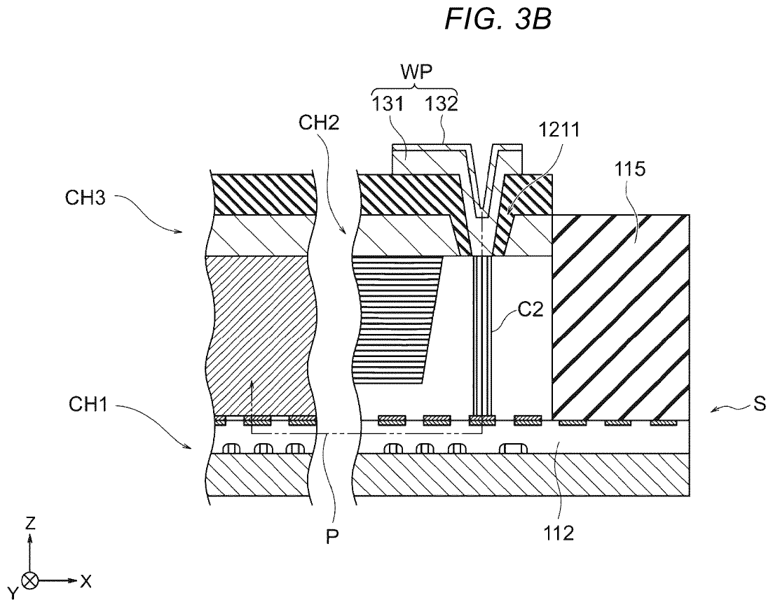

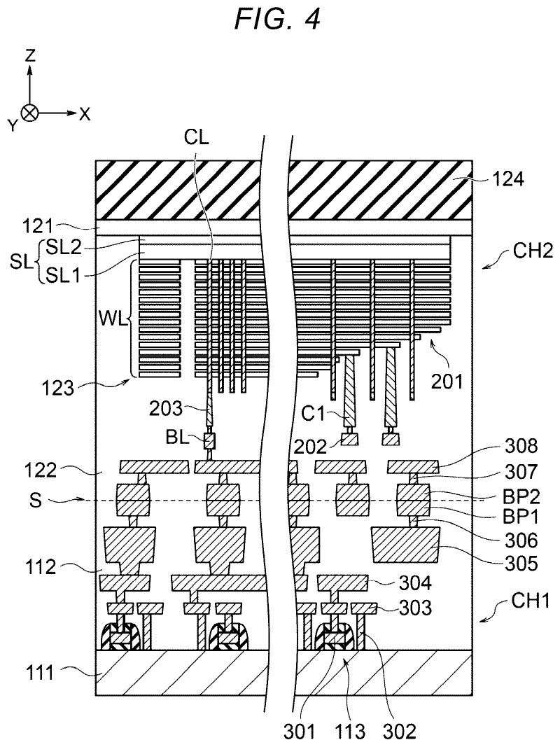

FIG. 4 is a sectional view showing one example of configurations of the memory cell array 123 and the transistor 113 according to the first embodiment.

The array chip CH2 includes a multiple of word lines WL and a source line SL as an electrode layer inside the memory cell array 123. FIG. 4 shows a stepped structure portion 201 of the memory cell array 123. Each word line WL is electrically connected to a word wiring layer 202 via a respective contact plug C1. Each columnar portion CL penetrating the multiple of word lines WL is electrically connected to a bit line BL via a via plug 203, and is electrically connected to the source line SL. The source line SL includes a first layer SL1, which is a semiconductor layer, and a second layer SL2, which is a metal layer.

The circuit chip CH1 includes a multiple of the transistors 113. Each transistor 113 includes a gate electrode 301, which is provided across a gate insulating film on the semiconductor substrate 111, and source and drain diffusion layers (not shown) provided in the semiconductor substrate 111. Also, the circuit chip CH1 includes a multiple of contact plugs 302, which are provided on the gate electrode 301, the source diffusion layer, or the drain diffusion layer of the transistor 113, a wiring layer 303, which is provided on the contact plug 302 and includes a multiple of wires, and a wiring layer 304, which is provided on the wiring layer 303 and includes a multiple of wires.

The circuit chip CH1 further includes a wiring layer 305, which is provided on the wiring layer 304 and includes a multiple of wires, a multiple of via plugs 306 provided on the wiring layer 305, and a multiple of metal pads BP1 provided on the via plug 306. Each metal pad BP1 is, for example, a copper (Cu) layer or an aluminum (Al) layer.

The array chip CH2 includes a multiple of metal pads BP2, which are provided on the metal pad BP1, and a multiple of via plugs 307 provided on the metal pad BP2. Also, the array chip CH2 includes a wiring layer 308, which is provided on the via plug 307 and includes a multiple of wires. Each metal pad BP2 is, for example, a copper layer or an aluminum layer.

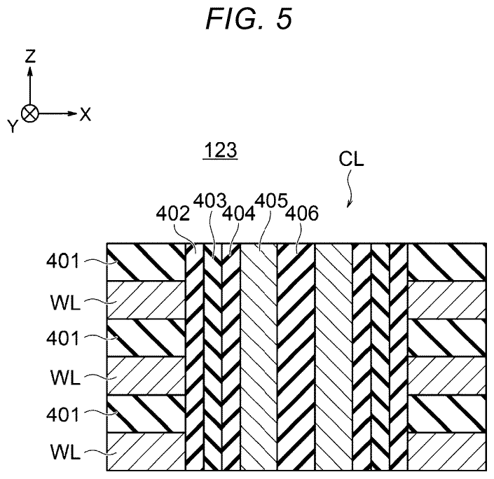

FIG. 5 is a sectional view showing one example of a configuration of the columnar portion CL according to the first embodiment.

As shown in FIG. 5, the memory cell array 123 includes the multiple of word lines WL and a multiple of insulating layers 401 stacked alternately on the interlayer insulating film 122 (refer to FIG. 4). The word line WL is, for example, a tungsten (W) layer. The insulating layer 401 is, for example, a silicon oxide film.

The columnar portion CL includes a block insulating film 402, a charge storage layer 403, a tunnel insulating film 404, a channel semiconductor layer 405, and a core insulating film 406, in that order. The charge storage layer 403 is, for example, a silicon nitride film, and is formed on the block insulating film 402 that is on side faces of the word line WL and the insulating layer 401. The charge storage layer 403 may also be a semiconductor layer such as a polysilicon layer. The channel semiconductor layer 405 is, for example, a polysilicon layer, and is formed on the tunnel insulating film 404 that is on a side face of the charge storage layer 403. The block insulating film 402, the tunnel insulating film 404, and the core insulating film 406 are, for example, silicon oxide films or metal insulating films.

Next, a method of manufacturing the semiconductor device 1 will be described.

FIGS. 6A to 6M are sectional views showing one example of a method of manufacturing the semiconductor device 1 according to the first embodiment.

Firstly, as shown in FIG. 6A, an array wafer W2 is prepared. Preparation of the array wafer W2 includes a process of forming the memory cell array 123 on the semiconductor substrate 121 and a process of applying a protective film 125 onto the interlayer insulating film 122. The protective film 125 is, for example, an alkali soluble film. The process of applying the protective film 125 may be omitted.

After preparing the array wafer W2, edge trimming of the array wafer W2 is carried out, as shown in FIG. 6B. After carrying out edge trimming, a protective tape BT is attached to the array wafer W2. The protective tape BT is a protective tape used in back grinding of the array wafer W2. After attaching the protective tape BT, back grinding of the array wafer W2 is carried out. By back grinding being carried out, the semiconductor substrate 121 becomes thinner.

After back grinding is carried out, a dicing tape DT1 is attached to the array wafer W2, as shown in FIG. 6C. After the dicing tape DT1 is attached, the protective tape BT is detached. After the protective tape BT is removed, a debonded face of the protective film 125 is cleaned. After the debonded face of the protective film 125 is cleaned, dicing of the array wafer W2 is carried out. By dicing being carried out, the array wafer W2 is divided into a multiple of the array chip CH2. The dicing process need not be after cleaning the debonded face of the protective film 125. It is sufficient that the dicing process is carried out before the multiple of the array chip CH2 and a multiple of the functional chip CH3 are joined on a circuit wafer W1 to be described hereafter.

After dicing is carried out, the separated multiple of array chips CH2 are transferred to a dicing tape DT2, as shown in FIG. 6D. The process of transferring to the dicing tape DT2 may be omitted. After the multiple of array chips CH2 are transferred to the dicing tape DT2, the protective film 125 is replaced. The process of replacing the protective film 125 may be omitted. After the protective film 125 is replaced, a pre-joining process is carried out. The pre-joining process is a preprocessing for joining the array chip CH2 to the circuit wafer W1. The pre-joining process includes, for example, an N₂ plasma processing and a process of washing with water.

With regard to the functional chip CH3 too, preparation for joining separated functional chips CH3 to the circuit wafer W1 is carried out by, for example, conducting the same process as for the array chip CH2 (FIGS. 6A to 6D). That is, firstly, a wafer (that is, the semiconductor substrate 121) on which the functional chip CH3 before division is formed is prepared. Next, wafer edge trimming, attachment of the protective tape BT, and back grinding are carried out in that order. Next, attachment of the dicing tape DT1, removal of the protective tape BT, cleaning of the debonded face of the protective film 125, and dicing are carried out in that order, whereby the functional chip CH3 is divided. Next, transfer to the dicing tape DT2, replacement of the protective film 125, and a pre-joining process are carried out in that order. The process of transferring to the dicing tape DT2 and the process of replacing the protective film 125 may be omitted. A method of manufacturing the functional chip CH3 is not limited to the above method.

Also, as shown in FIG. 6E, the circuit wafer W1 is prepared. Preparation of the circuit wafer W1 includes a process of forming the transistor 113 on the semiconductor substrate 111.

After the circuit wafer W1 is prepared, a protective film 114 is applied, as shown in FIG. 6F. The process of applying the protective film 114 may be omitted. After the protective film 114 is applied, division of the transistor 113 on the semiconductor substrate 111 is carried out using laser grooving. The process of dividing the transistor 113 may be omitted. For example, when the circuit wafer W1 to be described hereafter, on which a multiple of the array chip CH2 and a multiple of the functional chip CH3 are joined, is divided into a multiple of the circuit chip CH1, the transistor 113 may be divided at the same time. Laser grooving is carried out in accordance with a size of the circuit chip CH1. Division of the transistor 113 may be carried using another method, such as blade dicing, or stealth dicing using a laser.

After division of the transistor 113 is carried out, the protective film 114 is removed, as shown in FIG. 6G. After the protective film 114 is removed, a pre-joining process is carried out on the circuit wafer W1. After the pre-joining process is carried out on the circuit wafer W1, a multiple of the array chip CH2 and a multiple of the functional chip CH3 are joined onto the circuit wafer W1. When joining the multiple of the array chip CH2 and the multiple of the functional chip CH3 onto the circuit wafer W1, annealing of the circuit wafer W1, the array chip CH2, and the functional chip CH3 is carried out. By the array chip CH2 and the functional chip CH3 being joined onto the circuit wafer W1, the metal pads BP1 and BP2 are joined, as shown in FIGS. 3 and 4. By the metal pads BP1 and BP2 being joined, joining of the array chip CH2 to the circuit wafer W1 is carried out in such a way that the circuit wafer W1 (that is, the circuit chip CH1) and the array chip CH2 are electrically connected. Also, joining of the functional chip CH3 to the circuit wafer W1 is carried out in such a way that the circuit wafer W1 and the functional chip CH3 are electrically connected. Annealing may be carried out in a forming gas (for example, a reducing gas in which hydrogen and nitrogen are mixed).

After the array chip CH2 and the functional chip CH3 are joined to the circuit wafer W1, the member 115 is formed on the circuit wafer W1, the array chip CH2, and the functional chip CH3, as shown in FIG. 6H. The member 115 is of, for example, a resin such as an epoxy resin. The member 115 may also be of a material other than a resin, such as SiO₂. After the member 115 is formed, beveling of the member 115 is carried out.

After beveling of the member 115 is carried out, back grinding of the member 115 is carried out, as shown in FIG. 6I. After back grinding is carried out, degassing and annealing (that is, degassing annealing) of the member 115 is carried out. By back grinding and degassing annealing being carried out, a height of an upper face of the member 115 becomes approximately the same as a height of the upper face of the semiconductor substrate 121 of the array chip CH2 and the functional chip CH3. Back grinding is carried out using, for example, chemical mechanical polishing (CMP).

In FIGS. 6J to 6M, a sectional view indicated by reference sign B is a view in which a broken line frame Dj to Dm in a sectional view indicated by reference sign A is enlarged. The view of reference sign A is merely an auxiliary view for representing a range of the broken line frame Dj to Dm (that is, a range of the enlarged view of reference sign B), and is shown to have the same external appearance regardless of process progression.

After back grinding and degassing annealing of the member 115 is carried out, the recessed portion 1211 is formed in the semiconductor substrate 121, as shown in FIG. 6J. That is, the recessed portion 1211, which penetrates from the upper face to the lower face of the semiconductor substrate 121, is formed in the semiconductor substrate 121, which is provided on the upper face side of the array chip CH2. By the recessed portion 1211 being formed, an upper end of the contact plug C2 is exposed. The recessed portion 1211 is formed using, for example, lithography or reactive ion etching (RIE).

After the recessed portion 1211 is formed, the insulating film 124 is formed, as shown in FIG. 6K. The insulating film 124 is formed, for example, on a side face of the recessed portion 1211 and on the semiconductor substrate 121. The insulating film 124 is formed using, for example, lithography or curing. The insulating film 124 has an aperture in the recessed portion 1211.

After the insulating film 124 is formed, a seed layer (not shown) is formed. The seed layer includes, for example, titanium (Ti). The seed layer is, for example, formed over a whole surface of an underlayer (that is, the insulating film 124 and the upper end of the contact plug C2) using sputtering or the like. After the seed layer is formed, a resist 116 is patterned using photolithography in such a way as to have an aperture 116a in a position in which the metal pad WP is formed, as shown in FIG. 6L. After the resist 116 is patterned, the metal members 131 and 132 are formed inside the aperture 116a using a plating method. By the seed layer and the metal members 131 and 132 being formed, the metal pad WP is formed on the upper face of the array chip CH2. More specifically, the metal pad WP is configured integrated with a wire extending from the bottom face of the recessed portion 1211 to above the semiconductor substrate 121, whereby the metal pad WP provided above the semiconductor substrate 121 is formed.

After the metal pad WP is formed, the resist 116 is detached, as shown in FIG. 6M. After the resist 116 is detached, the seed layer (not shown) other than the seed layer under the metal pad WP is removed. After the seed layer is removed, under bump metal (UBM) plating (not shown) is formed. The UBM plating is formed using, for example, wet plating. After the UBM plating is formed, dicing is carried out. By dicing being carried out, the circuit wafer W1 is divided into a multiple of the circuit chip CH1 (that is, the semiconductor chips 30 to 33). In FIG. 6M, two circuit chips CH1 separated by dicing are shown in a separated state. In the example shown in FIG. 6M, the insulating film 124 exists on the member 115 on a right end of the array chip CH2. However, the insulating film 124 may be removed from above the member 115 before dicing, as shown in FIG. 3A.

After the semiconductor chips 30 to 33 are separated, a process of assembling a package by mounting the separated semiconductor chips 30 to 33 above the wiring substrate 10 is carried out. By the package assembly process being carried out, the semiconductor device 1 shown in FIGS. 1 and 2 is completed.

Before dividing the circuit wafer W1 into the semiconductor chips 30 to 33, electrical characteristics of the semiconductor chips 30 to 33 may be measured by connecting a wire to the metal pad WP. By measuring the electrical characteristics of the semiconductor chips 30 to 33, selection of the semiconductor chips 30 to 33 can be carried out. Consequently, the metal pad WP can be used as a probe terminal before dividing the circuit wafer W1 into the semiconductor chips 30 to 33.

FIG. 7 is a drawing showing one example of sizes of the array chip CH2 and the functional chip CH3 in the semiconductor device 1 according to the first embodiment. In FIG. 7, reference sign A is a plan view of the array chip CH2 and the functional chip CH3 joined on the circuit chip CH1. Reference sign B is a front view of the array chip CH2 and the functional chip CH3 joined on the circuit chip CH1. Reference sign C is a side view of the array chip CH2 and the functional chip CH3 joined on the circuit chip CH1.

In the example shown in FIG. 7, the circuit chip CH1, the array chip CH2, and the functional chip CH3 have a rectangular form when seen from the Z direction (that is, in plan view). As shown in FIG. 7, the area of the array chip CH2 is smaller than the area of the circuit chip CH1. More specifically, in the example shown in FIG. 7, a dimension in the Y direction of the array chip CH2 is equal to a dimension in the Y direction of the circuit chip CH1. In the example shown in FIG. 7, the Y direction is a direction perpendicular to a direction in which the array chip CH2 and the functional chip CH3 neighbor each other (that is, the X direction), and to a thickness direction of the circuit chip CH1 (that is, the Z direction). Also, a dimension in the X direction of the array chip CH2 is smaller than a dimension in the X direction of the circuit chip CH1.

As shown in FIG. 7, the area of the functional chip CH3 is also smaller than the area of the circuit chip CH1. More specifically, in the example shown in FIG. 7, a dimension in the Y direction of the functional chip CH3 is equal to the dimension in the Y direction of the circuit chip CH1. Also, a dimension in the X direction of the functional chip CH3 is smaller than a dimension in the X direction of the circuit chip CH1. In the example shown in FIG. 7, the area of the array chip CH2 is smaller than the area of the functional chip CH3. A magnitude relationship between the area of the array chip CH2 and the area of the functional chip CH3 may be the reverse of the case shown in FIG. 7. The array chip CH2 and the functional chip CH3 are joined in the regions R1 and R2, which differ from each other, on the upper face of the circuit chip CH1.

According to the example shown in FIG. 7, the dimension in the Y direction of the array chip CH2 is equal to the dimension in the Y direction of the functional chip CH3. The dimension in the Y direction of the array chip CH2 being equal to the dimension in the Y direction of the functional chip CH3 means that when, for example, power supply characteristics of the array chip CH2 are improved using a passive component in the functional chip CH3, power supply characteristics can be improved evenly for each bit line BL of the array chip CH2.

Also, according to the example shown in FIG. 7, the dimensions in the Y direction of the array chip CH2 and the functional chip CH3 are equal to the dimension in the Y direction of the circuit chip CH1, and a total value of the dimensions in the X direction of the array chip CH2 and the functional chip CH3 is slightly smaller than the dimension in the X direction of the circuit chip CH1. In other words, a total value of the area of the array chip CH2 and the area of the functional chip CH3 is slightly smaller than the area of the upper face of the circuit chip CH1. Consequently, approximately the whole region of the upper face of the circuit chip CH1 can be filled with the array chip CH2 and the functional chip CH3. In the example shown in FIG. 7, the dimension in the X direction of the array chip CH2 is smaller than the dimension in the X direction of the functional chip CH3. A magnitude relationship between the dimension in the X direction of the array chip CH2 and the dimension in the X direction of the functional chip CH3 may be the reverse of the case shown in FIG. 7.

According to the example shown in FIG. 7, approximately the whole region of the upper face of the circuit chip CH1 can be filled with the array chip CH2 and the functional chip CH3. As a result, the amount of resin (that is, the member 115) that is used to fill an airspace in the upper face of the circuit chip CH1 can be reduced as much as possible. As the amount of resin used, which has a large difference in linear expansion coefficient with respect to the circuit chip CH1, can be reduced, warping of the semiconductor chips 30 to 33 can be suppressed. The number of process steps also may be reduced by omitting the formation of the member 115. By reducing the number of process steps, a shortening of manufacturing time and a reduction in material can be achieved. As a result of this, a reduction in manufacturing cost of the semiconductor device 1 can be expected.

According to the first embodiment, as heretofore described, the semiconductor device 1 includes at least one of the semiconductor chips 30 to 33 having the circuit chip CH1, the array chip CH2, and the functional chip CH3. The array chip CH2 is joined to the circuit chip CH1 in the first region R1 on the upper face of the circuit chip CH1, in such a way as to be electrically connected to the circuit chip CH1. The functional chip CH3 is joined to the circuit chip CH1 in the second region R2 on the upper face of the circuit chip CH1, in such a way as to be electrically connected to the circuit chip CH1. The array chip CH2 and the functional chip CH3 have areas smaller than the area of the circuit chip CH1.

As a result, even if a difference arises between an element area of the array chip CH2 and an element area of the circuit chip CH1 due to a miniaturization of the memory cell array 123, a region above the circuit chip CH1 (that is, an airspace in the second region R2) caused by the difference can be filled with the functional chip CH3. By filling the region on the circuit chip CH1 with the functional chip CH3, assembly risks, such as chip inclination, can be reduced. That is, by eliminating a step region between the circuit chip CH1 and the array chip CH2, assembly of the semiconductor device 1 by stacking (that is, die bonding) of the semiconductor chips 30 to 33 can be carried out easily and appropriately.

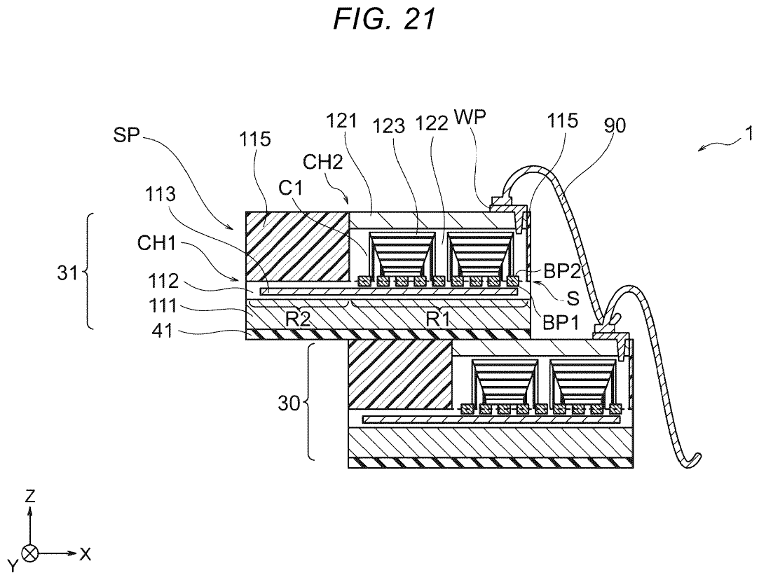

FIG. 21 is a sectional view showing one example of a configuration of the semiconductor chips 30 and 31 in the semiconductor device 1 according to a comparative example. In the example shown in FIG. 21, a spacer SP made of resin is disposed in a region on the circuit chip CH1. According to the example shown in FIG. 21, a step region between the circuit chip CH1 and the array chip CH2 can be eliminated. However, as the spacer SP made of resin does not have an electrical function, the region on the circuit chip CH1 cannot be effectively utilized electrically.

In response to this, according to the first embodiment, the region on the circuit chip CH1 is filled not by the spacer SP made of resin or a dummy chip, but by the functional chip CH3, whereby the region on the circuit chip CH1 can be effectively utilized electrically. In other words, the region on the circuit chip CH1 can be used in improving an electrical performance of the semiconductor device 1. Also, a difference between a linear expansion coefficient of the functional chip CH3 and a linear expansion coefficient of the circuit chip CH1 is smaller than a difference between a linear expansion coefficient of the spacer SP made of resin and the linear expansion coefficient of the circuit chip CH1. Consequently, warping of the semiconductor chips 30 to 33 caused by a difference in linear expansion coefficient can be reduced in comparison with a case in which the spacer SP made of resin is provided.

The following modifications can be applied to the first embodiment.

### First Modification

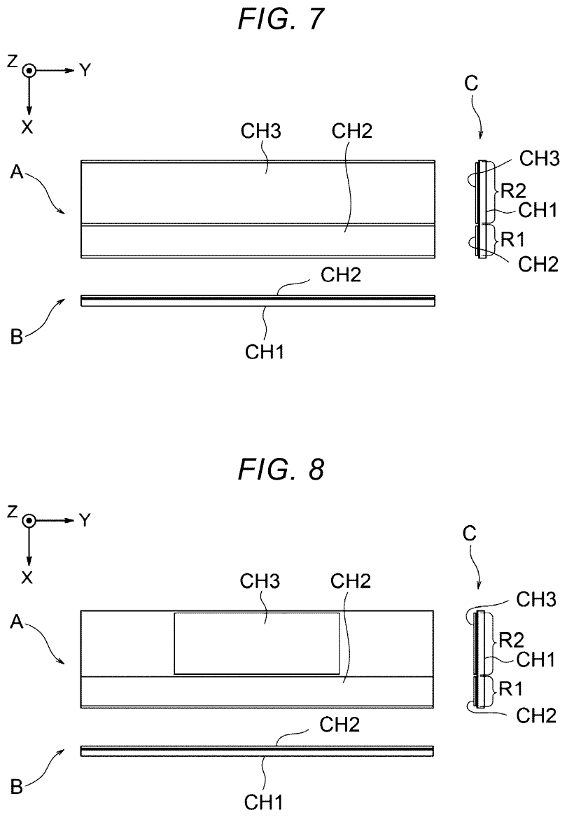

Firstly, with regard to a first modification of the first embodiment, in which the dimension in the Y direction of the functional chip CH3 is smaller than the dimension in the Y direction of the array chip CH2, a description will be given centered on differences from the heretofore described embodiment. FIG. 8 is a drawing showing sizes of the array chip CH2 and the functional chip CH3 in the semiconductor device 1 according to the first modification of the first embodiment.

In FIG. 7, an example in which the dimension in the Y direction of the functional chip CH3 is equal to the dimension in the Y direction of the array chip CH2 is shown. As opposed to this, in the example shown in FIG. 8, the dimension in the Y direction of the functional chip CH3 is smaller than the dimension in the Y direction of the array chip CH2. More specifically, an end portion in a −Y direction of the functional chip CH3 is positioned farther to the +Y direction than an end portion in the −Y direction of the circuit chip CH1. Also, an end portion in the +Y direction of the functional chip CH3 is positioned farther to the −Y direction than an end portion in the +Y direction of the circuit chip CH1. More specifically, the functional chip CH3 is positioned in a central portion of the second region R2 in the Y direction.

According to the example shown in FIG. 8, the functional chip CH3 can be formed to a size such that the functional chip CH3 achieves a necessary performance; as a result, the manufacturing cost of the functional chip CH3 can be reduced.

### Second Modification

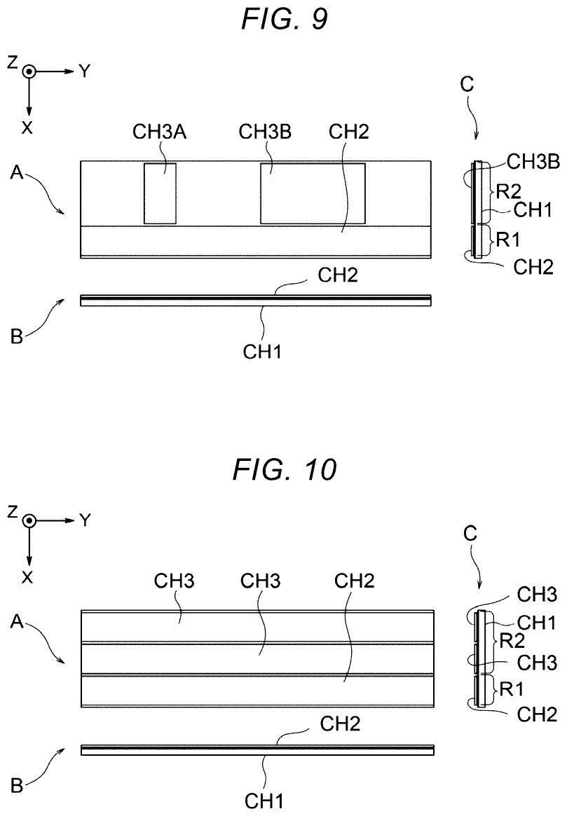

Next, with regard to a second modification of the first embodiment, in which a multiple of functional chips CH3A and CH3B whose sizes differ from each other are provided in the Y direction, a description will be given centered on differences from the heretofore described embodiment. FIG. 9 is a drawing showing sizes of the array chip CH2 and the functional chips CH3A and CH3B in the semiconductor device 1 according to the second modification of the first embodiment. In the example shown in FIG. 9, the two functional chips CH3A and CH3B whose sizes differ from each other are disposed across an interval in the Y direction in the second region R2. An area of the functional chip CH3A is smaller than an area of the functional chip CH3B. That is, a dimension in the Y direction of the functional chip CH3A is smaller than a dimension in the Y direction of the functional chip CH3B. Also, a dimension in the X direction of the functional chip CH3A is equal to a dimension in the X direction of the functional chip CH3B. A function of the functional chip CH3A may differ from a function of the functional chip CH3B. For example, while the functional chip CH3A includes a step-up circuit, the functional chip CH3B may include a capacitor that accumulates voltage stepped-up by the step-up circuit.

According to the example shown in FIG. 9, restrictions on areas, quantities, and functions of the functional chips CH3A and CH3B can be removed; as a result, freedom of design of the semiconductor device 1 can be increased.

### Third Modification

Next, with regard to a third modification of the first embodiment, in which a multiple of the functional chips CH3 whose dimension in the Y direction is equal to the dimension in the Y direction of the array chip CH2 are provided, a description will be given centered on differences from the heretofore described embodiment. FIG. 10 is a drawing showing sizes of the array chip CH2 and the functional chip CH3 in the semiconductor device 1 according to the third modification of the first embodiment. FIG. 7 shows an example in which one functional chip CH3 whose dimension in the Y direction is equal to the dimension in the Y direction of the array chip CH2 is provided. As opposed to this, in the example shown in FIG. 10, two functional chips CH3 whose dimension in the Y direction is equal to the dimension in the Y direction of the array chip CH2 are disposed to neighbor each other in the X direction in the second region R2. Areas of the two functional chips CH3 are equal to each other.

According to the example shown in FIG. 10, in the same way as that in FIG. 7, power supply characteristics can be improved evenly for each bit line BL of the array chip CH2. Also, approximately the whole region of the upper face of the circuit chip CH1 can be filled with the array chip CH2 and the functional chip CH3; as a result, warping of the semiconductor chips 30 to 33 can be suppressed.

### Fourth Modification

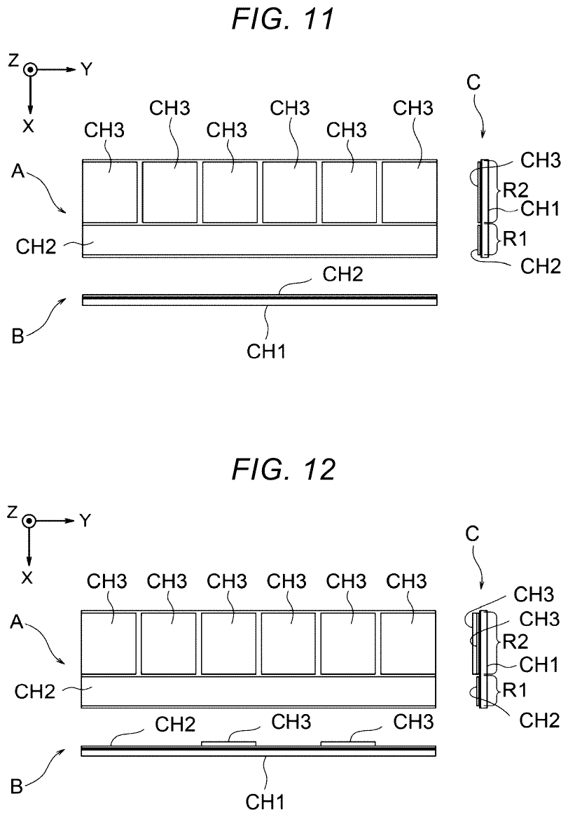

Next, with regard to a fourth modification of the first embodiment, in which a multiple of the functional chip CH3 whose sizes are equal to each other are provided in the Y direction, a description will be given centered on differences from the heretofore described embodiment. FIG. 11 is a drawing showing sizes of the array chip CH2 and the functional chip CH3 in the semiconductor device 1 according to the fourth modification of the first embodiment. In the example shown in FIG. 11, a multiple of the functional chip CH3 whose sizes are equal to each other are disposed to neighbor each other in the Y direction in the second region R2. Functions of the multiple of the functional chip CH3 may be the same as each other, or may differ from each other.

The example shown in FIG. 11 is such that when, for example, the array chip CH2 is heated using a multiple of heaters as the multiple of functional chips CH3, an existence or otherwise of a regeneration of the array chip CH2 owing to a turning on or off of a corresponding heater can be controlled for each of a multiple of planes PLN (not shown) of the array chip CH2. The multiple of planes PLN are memory regions that can be controlled independently of each other.

### Fifth Embodiment

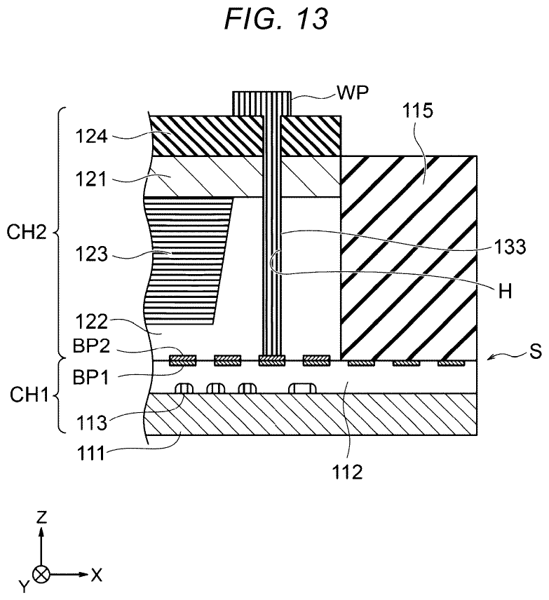

Next, with regard to a fifth modification of the first embodiment, in which sizes of the functional chips CH3 are not uniform, a description will be given centered on differences from the heretofore described embodiment. FIG. 12 is a drawing showing sizes of the array chip CH2 and the functional chip CH3 in the semiconductor device 1 according to the fifth modification of the first embodiment. FIG. 11 shows an example in which a multiple of the functional chip CH3 whose sizes are equal to each other are disposed to neighbor each other in the Y direction in the second region R2. As opposed to this, in the example shown in FIG. 12, a multiple of the functional chip CH3 whose sizes (for example, thicknesses) are not uniform are disposed to neighbor each other in the Y direction in the second region R2.

According to the example shown in FIG. 12, a restriction on the thickness of the functional chip CH3 can be removed; as a result, freedom of design of the semiconductor device 1 can be increased.

### Sixth Modification

Next, with regard to a sixth modification of the first embodiment, in which the metal pad WP and the circuit chip CH1 are electrically connected via a via 133 that penetrates the array chip CH2, a description will be given centered on differences from the heretofore described embodiment. FIG. 13 is a sectional view showing the semiconductor device 1 according to the sixth modification of the first embodiment.

FIG. 6J shows an example in which the recessed portion 1211 is formed in the semiconductor substrate 121 until the upper end of the contact plug C2, which is formed on an underlayer of the semiconductor substrate 121, is exposed, and the metal pad WP is formed above the recessed portion 1211. As opposed to this, in the example shown in FIG. 13, the via 133, which electrically connects the metal pad WP and the circuit chip CH1, is provided below the metal pad WP.

The example shown in FIG. 13 is such that after a via hole H that penetrates the array chip CH2 is formed, formation of the via 133, which fills the via hole H, and formation (that is, rewiring) of the metal pad WP on an upper end of the via 133 can be carried out. Consequently, no processing of the recessed portion 1211 is needed; as a result, manufacturing man-hours can be reduced.

### Seventh Modification

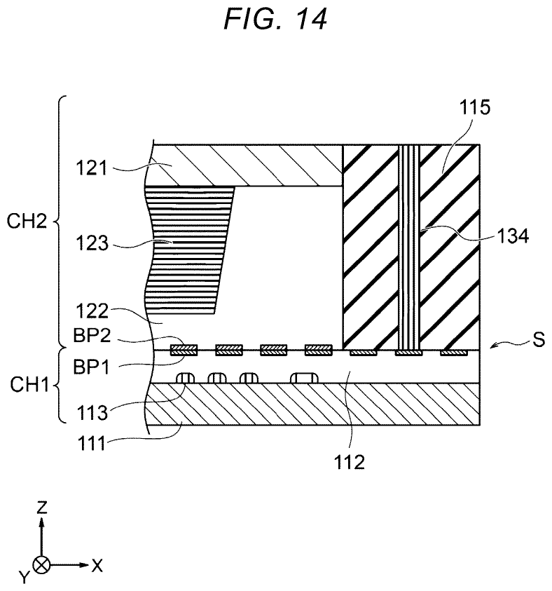

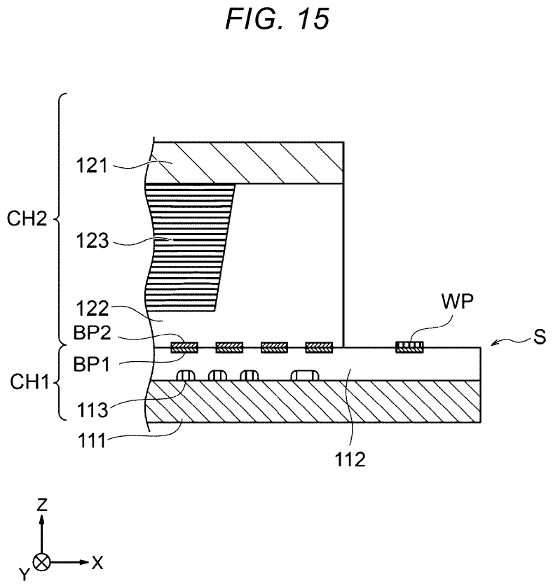

Next, with regard to a seventh modification of the first embodiment, in which the metal pad WP is not formed, a description will be given centered on differences from the heretofore described embodiment. FIG. 14 is a sectional view showing the semiconductor device 1 according to the seventh modification of the first embodiment. In the example shown in FIG. 14, a conductive columnar portion 134 that penetrates the member 115 (that is, resin, SiO₂, or the like) is provided. The columnar portion 134 is, for example, formed as a bump of the bonding wire 90 before the member 115 is formed. Alternatively, the columnar portion 134 is formed to fill a hole that penetrates the member 115 after the hole is formed.

According to the example shown in FIG. 14, formation (that is, rewiring) of the metal pad WP can be omitted; as a result, manufacturing man-hours can be reduced. Also, as there is no need to form the via hole H that penetrates the array chip CH2 (that is, there is no need to provide a space for forming the via hole H in the array chip CH2), the size of the array chip CH2 can be reduced. As the size of the array chip CH2 can be reduced, the number of chips obtained from a wafer can be increased. As the number of chips obtained from a wafer can be increased, cost can be reduced. Furthermore, distance can be maintained between the columnar portion 134 and the array chip CH2 because of the member 115 (that is, resin, SiO₂, or the like); as a result, the array chip CH2 being directly damaged when carrying out wire bonding can be avoided. Because of this, cracking occurring in the array chip CH2 when carrying out wire bonding can be restricted.

### Eighth Modification

Next, with regard to an eighth modification of the first embodiment, in which the metal pad WP is formed on the circuit chip CH1, a description will be given centered on differences from the heretofore described embodiment. FIG. 15 is a sectional view showing the semiconductor device 1 according to the eighth modification of the first embodiment. In the example shown in FIG. 15, the metal pad WP is provided on the circuit chip CH1. Also, in the example shown in FIG. 15, the member 115 (that is, resin, SiO₂, or the like) is not provided on the circuit chip CH1.

According to the example shown in FIG. 15, the metal pad WP can be formed directly on the circuit chip CH1; as a result, manufacturing man-hours can be reduced. Also, as the member 115 is not formed, manufacturing man-hours can be further reduced, and cost can be reduced. Also, the size of the array chip CH2 can be reduced in comparison with the example shown in FIG. 13; as a result, cost can be reduced.

### Ninth Modification

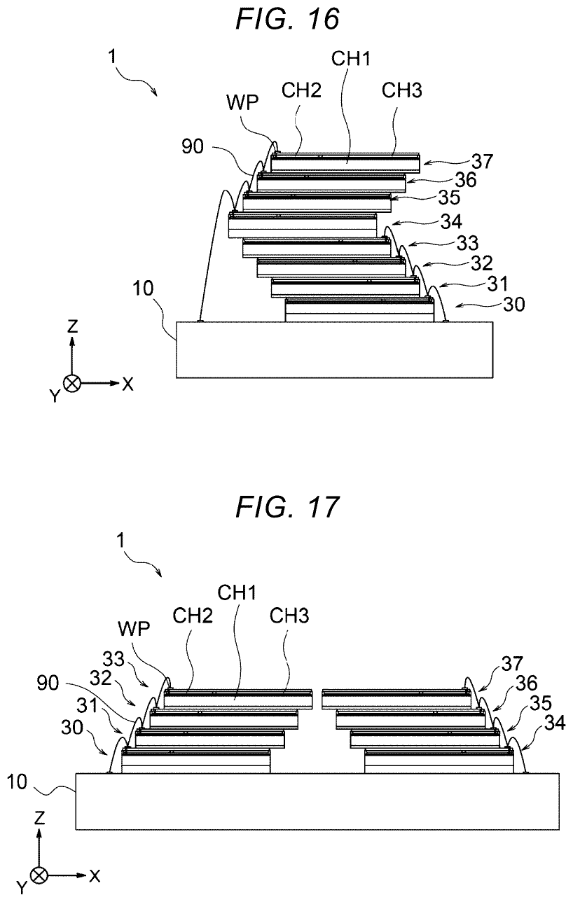

FIG. 16 is a side view showing the semiconductor device 1 according to a ninth modification of the first embodiment. In FIG. 16, and in FIGS. 17 to 20 to be described hereafter, a depiction of the semiconductor chip 20 shown in FIG. 1 is omitted. As shown in FIG. 16, the number of stacked semiconductor chips 30 to 37 may be increased with respect to the heretofore described embodiment. According to the example shown in FIG. 16, a storage capacity and freedom of design of the semiconductor device 1 can be increased.

### Tenth Modification

FIG. 17 is a side view showing the semiconductor device 1 according to a tenth modification of the first embodiment. In FIG. 17, the number of mounted semiconductor chips 30 to 37 may be increased in the X direction with respect to the heretofore described embodiment. According to the example shown in FIG. 17, the storage capacity and freedom of design of the semiconductor device 1 can be increased.

### Second Embodiment

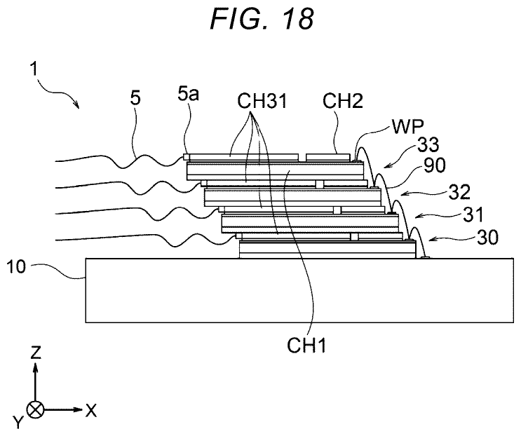

Next, with regard to a second embodiment in which a functional chip is a photoelectric conversion element, a description will be given centered on differences from the heretofore described embodiment. FIG. 18 is a side view showing one example of a configuration of the semiconductor device 1 according to the second embodiment. In the second embodiment, the semiconductor chip 30 (that is, a third semiconductor chip), the semiconductor chip 31 (that is, a fourth semiconductor chip), and the semiconductor chips 32 and 33 include a functional chip CH31 configured with a photoelectric conversion element.

As shown in FIG. 18, the semiconductor chips 30 to 33 further include an optical fiber terminal 5a disposed in a position differing from a position of the metal pad WP (that is, a second pad). In the example shown in FIG. 18, the optical fiber terminal 5a is disposed on a side face of the functional chip CH31 on a side opposite to that of a side face facing the array chip CH2.

The semiconductor device 1 according to the second embodiment is such that a transmission and reception of data to and from the functional chip CH31 is carried out via an optical fiber 5 connected to the optical fiber terminal 5a. Also, the semiconductor device 1 is such that a supply of power to the semiconductor chips 30 to 33 is carried out via the bonding wire 90 (that is, a second wire), which connects the wiring substrate 10 (that is, a second substrate) and the metal pad WP of the semiconductor chips 30 to 33.

The second embodiment is such that by including the functional chip CH31, which is configured of a photoelectric conversion element, a high-speed transmission of data to the functional chip CH31 can be carried out. As a result of this, a processing speed of the semiconductor device 1 can be caused to increase.

### First Modification

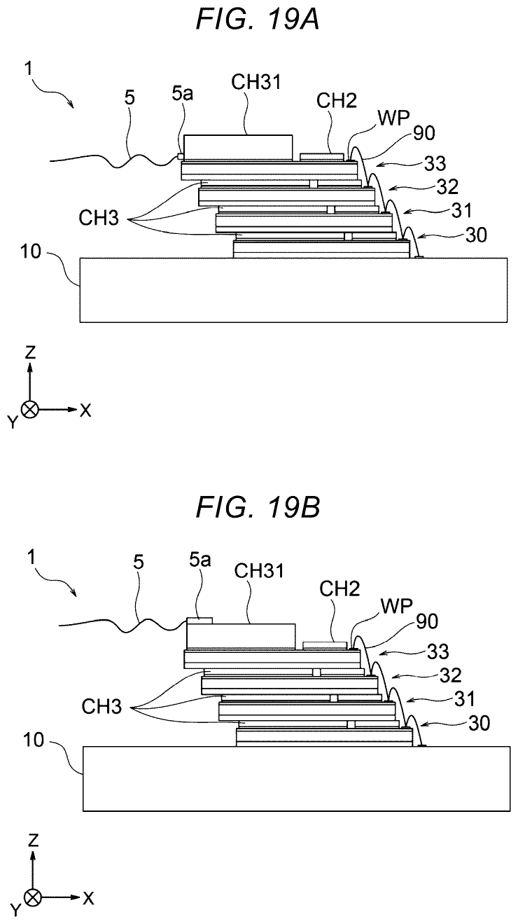

FIG. 19A is a side view showing the semiconductor device 1 according to a first modification of the second embodiment. In the example shown in FIG. 19A, the semiconductor chips 30 to 32 (that is, fifth semiconductor chips) stacked on the wiring substrate 10 (that is, a third substrate) include the functional chip CH3 that does not have a photoelectric conversion element. A specific example of the functional chip CH3 that does not have a photoelectric conversion element is as described in the first embodiment. Meanwhile, the uppermost semiconductor chip 33 disposed on the semiconductor chip 32 includes the functional chip CH3 configured with a photoelectric conversion element. Also, in the example shown in FIG. 19A, a thickness of the functional chip CH3 is greater than a thickness of the array chip CH2. The wiring substrate 10, the metal pad WP of the semiconductor chips 30 to 32 (that is, a fourth pad), and the metal pad WP of the semiconductor chip 33 (that is, a third pad) are connected by the bonding wire 90 (that is, a third wire).

According to the example shown in FIG. 19A, the photoelectric conversion element CH31 is disposed on the uppermost layer, meaning that even when the thickness of the photoelectric conversion element CH31 cannot be aligned with the thickness of the array chip CH2, an increase in the number of chips stacked and an increase in processing speed can be achieved, while avoiding assembly difficulty caused by an inclination of the semiconductor chips 30 to 33. Also, as the photoelectric conversion element CH31 can be disposed on the uppermost layer, a position of the optical fiber terminal 5a can be selected freely. For example, instead of disposing the optical fiber terminal 5a on a side face of the photoelectric conversion element CH31, as in FIG. 19A, the optical fiber terminal 5a can be disposed on an upper face of the photoelectric conversion element CH31, as shown in FIG. 19B.

### Second Modification

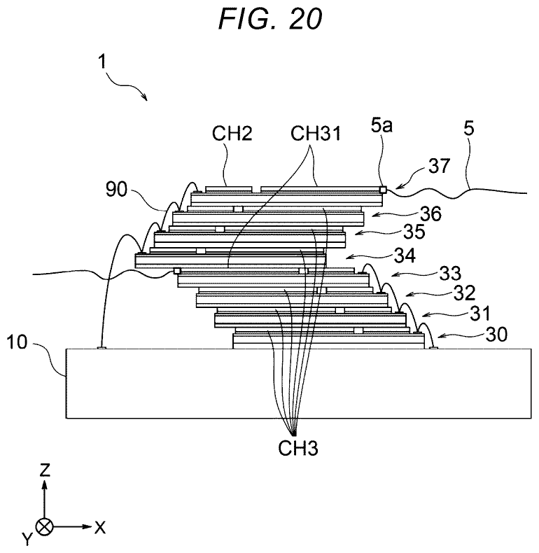

FIG. 20 is a side view showing the semiconductor device 1 according to a second modification of the second embodiment. As shown in FIG. 20, the number of stacked semiconductor chips 33 and 37, which include the functional chip CH31 configured with a photoelectric conversion element, and semiconductor chips 30 to 32 and 34 to 36, which include the functional chip CH3 that does not have a photoelectric conversion element, may be increased. In the example shown in FIG. 20, the semiconductor chip 33, which includes the functional chip CH31 configured of a photoelectric conversion element, is disposed between the semiconductor chips 34 and 35, which include the functional chip CH3 that does not have a photoelectric conversion element. According to the example shown in FIG. 20, freedom of design of the semiconductor device 1 can be increased.

### Other Embodiments

In the heretofore described embodiments, the array chip CH2 of the semiconductor chips 30 to 33 includes a three-dimensional memory cell array such that a multiple of memory cells are disposed three-dimensionally. Instead of this, the array chip CH2 may be a two-dimensional memory cell array, an image sensor, or the like. Also, another memory element such as a DRAM or a SRAM may be used instead of a NAND flash memory. The array chip CH2 may be a CMOS circuit element or the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first chip;
a second chip that is joined to a first region of an upper face of the first chip, the second chip being electrically connected to the first chip and having a surface area facing the first chip that is smaller than an area of the upper face of the first chip; and
a third chip that is joined to a second region of the upper face of the first chip, the third chip being electrically connected to the first chip and having a surface area facing the first chip that is smaller than the area of the upper face of the first chip, wherein an electrical function of the third chip differs from an electrical function of the second chip.

2. The semiconductor device according to claim 1, wherein a total area of surfaces of the second chip and the third chip that face the first chip is smaller than the area of the upper face of the first chip.

3. The semiconductor device according to claim 1, wherein the area of the surface of the second chip facing the first chip differs from the area of the surface of the third chip facing the first chip.

4. The semiconductor device according to claim 1, wherein a thickness of the second chip differs from a thickness of the third chip.

5. The semiconductor device according to claim 1, wherein
the first chip includes a CMOS circuit, and
the second chip includes a non-volatile memory.

6. The semiconductor device according to claim 5, wherein the third chip includes a photoelectric conversion element.

7. The semiconductor device according to claim 6, further comprising:
a pad disposed on one of the first, second, and third chips; and
an optical fiber connection terminal disposed in a position of the first, second, and third chips different from a position of the pad.

8. The semiconductor device according to claim 7, wherein transmission and reception of data to and from the photoelectric conversion element is carried out via an optical fiber connected to the optical fiber connection terminal, and a supply of power to the first, second, and third chips is carried out via the pad.

9. A semiconductor package, comprising:
a substrate; and
a plurality of semiconductor devices, each including:
a first chip;
a second chip that is joined to a first region of an upper face of the first chip, the second chip being electrically connected to the first chip and having a surface area facing the first chip that is smaller than an area of the upper face of the first chip; and
a third chip that is joined to a second region of the upper face of the first chip, the third chip being electrically connected to the first chip and having a surface area facing the first chip that is smaller than the area of the upper face of the first chip, wherein an electrical function of the third chip differs from an electrical function of the second chip,
wherein the plurality of semiconductor devices includes a first semiconductor device disposed on the substrate, and a second semiconductor device disposed on the first semiconductor device.

10. The semiconductor package according to claim 9, wherein the plurality of semiconductor devices each includes a pad on an upper surface thereof.

11. The semiconductor package according to claim 10, further comprising a first wire that connects the substrate, the pad of the first semiconductor device, and the pad of the second semiconductor device.

12. The semiconductor package according to claim 11, wherein
the plurality of semiconductor devices further includes a third semiconductor device disposed on the substrate and a fourth semiconductor device disposed on the third semiconductor device.

13. The semiconductor package according to claim 12, further comprising a second wire that connects the substrate, the pad of the third semiconductor device, and the pad of the fourth semiconductor device.

14. The semiconductor package according to claim 9, wherein the plurality of semiconductor devices further includes a third semiconductor device that is disposed on the second semiconductor device, and the third chip of the third semiconductor device includes a photoelectric conversion element and the third chip of each of the first and second semiconductor devices does not include the photoelectric conversion element.

15. The semiconductor package according to claim 9, wherein
the first chip has a first metal pad disposed on the upper face of the first chip, and
the second chip has a second metal pad disposed on a lower face of the second chip to be joined to the first metal pad.

16. A semiconductor device manufacturing method, comprising:
forming a plurality of chips on a wafer, the plurality of chips including a first chip having a first area on an upper surface thereof; and
prior to dividing the chips, joining a second chip to the upper surface of the first chip, so that the second chip is electrically connected to the first chip, and joining a third chip, which has an electrical function different from an electrical function of the second chip, to the upper surface of the first chip, so that the third chip is electrically connected to the first chip, wherein a surface of the second chip facing the first chip has an area that is smaller than the first area and a surface of the third chip facing the first chip has an area that is smaller than the first area.

17. The semiconductor device manufacturing method according to claim 16, wherein a total area of the surface of the second chip facing the first chip and the surface of the third chip facing the first chip is smaller than the first area.

18. The semiconductor device manufacturing method according to claim 16, wherein
the first chip includes a plurality of first bonding pads formed on an upper surface thereof, and each of the second and third chips includes a plurality of second bonding pads formed on a lower surface thereof, and
the second chip and the third chip are each joined to the first chip by bonding the first bonding pads to the second bonding pads.

19. The semiconductor device manufacturing method according to claim 18, further comprising:
forming a pad on an upper surface of the second chip that is electrically connected to one of the first bonding pads of the first chip.

20. The semiconductor device manufacturing method according to claim 19, wherein the first chip is formed on a substrate that includes a power supply pad, and the pad on the upper surface of the second chip is connected to the power supply pad by a wire.
